(19) United States
(12) Patent Application Publication
(10) Pub. No.: US 2003/0122264 A1
(43) Pub. Date: Jul. 3, 2003

(54) Bond out chip and method for making same

(76) Inventors: Fong-Long Lin, Fremont, CA (US); Michael S. Briner, San Jose, CA (US)

Correspondence Address: GARY CARY WARE & FREIDENRICH LLP, 1755 EMBARCADERO ROAD, PALO ALTO, CA, 94303-3340, US

(21) Appl. No.: 10/033,546

(22) Filed: Dec. 27, 2001

(51) Int. Cl. H01L 23/48; H01L 23/52; H01L 29/40

(52) U.S. Cl. 257/784

(57) ABSTRACT

A bond out chip 60 for use with an in-circuit emulator. The bond out chip 60 is formed by use of a first chip 10a and an adjacent chip 10b. Chips 10a and 10b have architectures substantially identical to the standard production chips that chip 60 is used to analyze or emulate. The first chip 10a is formed with an active core portion 12a, while the production chip 10b is formed with a disabled core portion 12b. The core portion 12a of chip 10a is connected to the input/output buffers and pads 18b, 20b of the adjacent chip 10b, thereby forming bond out chip 60.

### FIELD OF THE INVENTION

The present invention generally relates to semiconductor devices, and more particularly to a bond out chip for use with an in-circuit emulator and a method for making the same.

### BACKGROUND OF THE INVENTION

Bond out chips are used in conjunction with in-circuit emulators (ICEs) for testing semiconductor devices, such as microcontrollers. An ICE may be used to record the operations of a microcontroller, such as processing and execution operations, thereby allowing engineers to view and analyze the function of the microcontroller. Some of these operations can be monitored by connecting an ICE to external ports of the microcontroller. However, in order to fully understand and analyze the internal operations of a microcontroller, it is often necessary to connect the emulator to locations within the microcontroller that can monitor internal address and data buses and that are not accessible from the external ports.

In order to access these locations and gain a better understanding of the operation of semiconductor devices, manufacturers typically create bond out chips. A bond out chip is a specially manufactured version of a chip that provides access to internal locations (e.g., address and data buses) within the chip through external pads that are relatively easily connected to an ICE. A bond out chip is typically slightly different in design from (e.g., larger than) the production chip it emulates, and has additional external pins, buffers and pads that are more accessible (e.g., spread out). As a result, bond out chips typically cannot share the same mask set as production chips, and often require a completely different design, mask set, and fabrication procedure.

The foregoing attributes cause the fabrication of bond out chips to be very costly and inefficient, since all of the processing elements and steps that are required for a production chip must typically be modified and repeated for a relatively small number of bond out chips. Furthermore, because a bond out chip will often have differences in size, design and operation relative to its associated production chip, its ability to accurately emulate certain aspects of the production chip will be limited and may require engineers to speculate and work around such differences in their analysis. Moreover, any change in the production chip will require an entirely new bond out chip, including an entirely new mask set, design and fabrication procedure, thereby undesirably increasing product development costs.

There is therefore a need for a new and improved bond out chip for use with an ICE and a method for making the same, which overcomes the previously delineated drawbacks of prior bond out chips and methods, and which utilizes a production chip in combination with the input/output buffers and pads of one or more adjacent chips that are disabled.

### SUMMARY OF THE INVENTION

A first non-limiting advantage of the present invention is that it provides a bond out chip for use with an ICE and a method for making the same, which overcomes the previously delineated drawbacks of prior bond out chips and methods.

A second non-limiting advantage of the present invention is that it provides a bond out chip that is substantially similar in construction to a standard production chip with the exception of one or more top connection layers, therefore allowing the bond out chip to utilize many of the same masks as the standard production chip.

A third non-limiting advantage of the present invention is that it provides a method for making a bond out chip that allows the bond out chip to be manufactured on the same wafer as production chips, thereby reducing production costs.

A fourth non-limiting advantage of the present invention is that it provides a bond out chip that is formed by a first chip, which is substantially similar in architecture to a production chip, in combination with the input/output pads and/or buffers of one or more adjacent chips on a wafer.

According to a first aspect of the present invention, a bond out chip is provided and includes a first chip; and a plurality of input/output pads which are disposed on at least one second chip adjacent to the first chip and which are communicatively coupled to the first chip.

According to a second aspect of the present invention, a bond out chip formed on a semiconductor wafer is provided. The bond out chip includes a first chip having an active core portion and an architecture that is substantially identical to a production chip with the exception of at least one connection layer; and an adjacent chip which is substantially identical in architecture to the first chip with the exception of the at least one connection layer and which includes a disabled core portion and a plurality of input/output buffers and pads which are communicatively coupled to the first chip and which are adapted to allow the first chip to be coupled to an in-circuit emulator.

According to a third aspect of the present invention, a method of manufacturing a bond out chip is provided. The method includes the steps of: forming a plurality of chips on a semiconductor wafer each having a core portion and input/output pads; activating the core portion of a first chip; disabling the core portion of at least one second chip which is adjacent to the first chip; connecting the first chip to the input/output pads of the at least one second chip; and removing the first chip and second chip together from the wafer, thereby forming a bond out chip.

These and other features, advantages, and objects of the invention will become apparent by reference to the following specification and by reference to the following drawings.

### BRIEF DESCRIPTION OF THE DRAWINGS

FIG. 1 is a schematic diagram illustrating a semiconductor chip that may be used as a production chip or as a portion of a bond out chip in accordance with the present invention.

FIG. 2 is a partial schematic diagram of a wafer including a bond out chip in accordance with the present invention.

FIG. 3 is a schematic diagram illustrating a bond out chip in accordance with the present invention.

FIG. 4 is a sectional view of the bond out chip shown in FIG. 3 illustrating the connection and interconnection layers.

### DETAILED DESCRIPTION OF THE PREFERRED EMBODIMENT OF THE INVENTION

Referring now to FIG. 1, there is shown a semiconductor device or chip 10 which may form a standard production chip or a portion of a bond out chip made in accordance with the present invention. Chip 10 is formed by use of a multi-layer circuit manufacturing process, such as a semiconductor manufacturing process. In the preferred embodiment, chip 10 is a conventional microcontroller, but in other alternate embodiments, chip 10 may be any other type of chip that may be analyzed by use of an in-circuit emulator. In the preferred embodiment, chip 10 includes a “core” portion 12 having a processing unit or micro-control unit (“MCU”) 14, a conventional logic and input/output control circuit 16, a conventional random access memory (“RAM”) unit 22, a conventional read-only memory (“ROM”) unit 24, and an erasable/programmable non-volatile memory unit 29, such as a flash memory unit. Chip 10 further includes a plurality of (e.g., two) conventional driver circuits 26, 28 for coupling the chip 10 to an emulator. In alternate embodiments, chip 10 may include any other number of driver circuits. As discussed more fully and completely below, chip 10 utilizes the same core portion 12 whether the chip 10 operates as a bond out chip or a standard production chip. As used herein, the term “production chip” will refer to a chip that the bond out chip is intended to emulate.

Chip 10 further includes input/output buffers 18, and input/output pads 20 for connecting the core portion 12 of chip 10 to external pins and/or signals. Chip 10 may also include additional input/output buffers and pads located in other regions of the chip. Furthermore, chip 10 and core portion 12 may include different or additional circuit portions, elements and/or units for use in the input, output and processing of data within and external to chip 10.

In the preferred embodiment of the invention, micro-control unit 14 includes a conventional and commercially available semiconductor processing device (e.g., a microprocessor). Micro-control unit 14 is communicatively coupled to logic and input/output control circuit 16 by use of buses 30, 32, 34, to RAM unit 22 by use of buses 30, 36, to ROM unit 24 by use of buses 30, 38, to flash memory unit 29 by use of buses 30, 40, to driver 26 by use of buses 30, 42, and to driver 28 by use of buses 30, 44. Logic and input/output control unit 16 is communicatively coupled to input/output buffers 18 by use of bus 46, and input/output buffers 18 are communicatively coupled to input/output pads 20 by use of bus 48. The foregoing connections can be made (e.g., the buses may be formed) in a known manner during the formation of one or more connection layers of chip 10.

Logic and input/output control circuit 16 is a conventional logic and input/output control circuit which operates with micro-control unit 14 to communicate control signals to and receive signals from input/output pads 20 through input/output buffers 18 when chip 10 is in an operational state.

Input/output buffers 18 include one or more conventional buffer circuits adapted to hold data which is communicated into and out of chip 10. Input/output pads 20 are conventional bonding pads, and may comprise metallized regions on the surface of chip 10 to which connections can be made, such as connections to external pins.

In the present invention, the driver circuits 26, 28 are conventional driver circuits that are adapted to allow an in-circuit emulator (ICE) to access operational data and control signals from chip 10. Particularly, an ICE can gain access to the internal operations of chip 10 for purposes of emulation by communicatively coupling to drivers 26, 28 through connection locations or nodes 52, 54, respectively. Each chip 10 will include drivers 26, 28, regardless of whether the chip 10 acts as a standard production chip or as a portion of a bond out chip. If the chip 10 is to operate as a standard production chip, the drivers 26, 28 are unnecessary and will be disabled in a conventional manner when the top connection layer of chip 10 is formed during the manufacturing process. Chip 10 further includes a pair of nodes or locations 56, 58, which are disposed between input/output buffers 18 and logic and input/output control unit 16, and which may be used to electrically and communicatively connect or disconnect buffers 18 and unit 16. Particularly, if the chip 10 is to operate as a standard production chip, the locations 56, 58 will be electrically coupled together in a conventional manner when the top connection layer of chip 10 is formed during the manufacturing process, thereby communicatively connecting buffers 18 and unit 16. As discussed more fully and completely below, if the chip 10 is to be used only for its input/output buffers 18 and pads 20 (i.e., as part of a bond out chip), locations 56, 58 will be electrically disconnected, thereby disabling the core portion 12 and allowing the buffers 18 and pads 20 to be connected to an adjacent core.

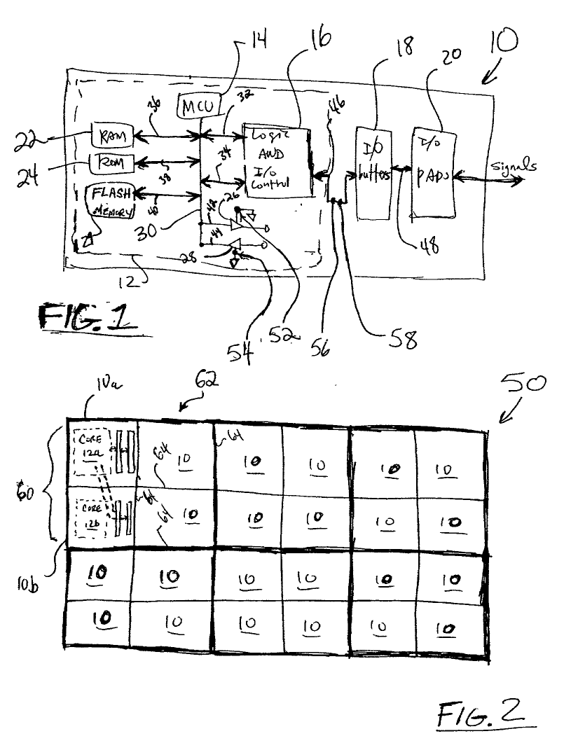

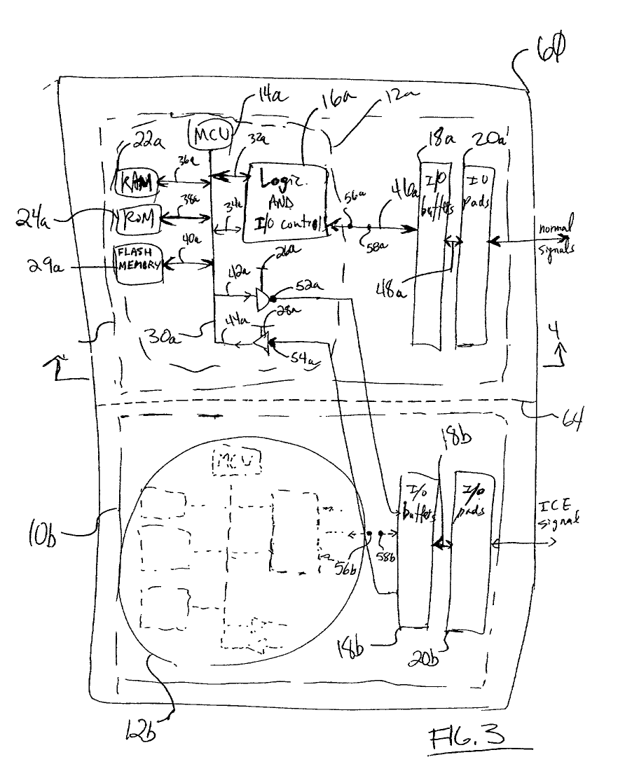

FIG. 2 illustrates a portion of a semiconductor wafer 50 on which a plurality of chips 10 are formed in a conventional manner. In the preferred embodiment, one of the manufacturing tools used to form wafer 50 is “stepper.” As known to those of ordinary skill in the art, a stepper images portions of the design onto the wafer 50 multiple times, but does so in a step-wise fashion over groups of chips 10. The grouping of chips is determined by the “reticle.” In the non-limiting example shown in FIG. 2, each reticle or reticle zone 62 defines two rows of two columns of chips 10 (a “two-by-two reticle layout”), and in alternate embodiments, each reticle zone 62 may comprise any other suitable number of chips. In FIG. 2, the outer boarder of each reticle zone 62 has been darkened for illustrative purposes to differentiate between each reticle on wafer 50.

When the chips 10 are formed, they are spaced apart, as shown in FIG. 2, in order to allow the chips 10 to be separated and removed from the wafer. Scribe lines 64 are formed between each of the spaced apart chips 10. The scribe lines 64 are used to assist in removing the chips 10 from the wafer 50, and separating the chips 10. Particularly, by cutting along the scribe lines 64, the chips 10 can be removed from the wafer 50 and/or separated from each other.

In order to form an ICE bond out chip 60, one or more of the reticle zones 62 on wafer 50 are designated for the bond out chip 60. Within the designated reticle zone(s) 62, a first chip 10a will be designated to operate as the “core” or active portion of the bond out chip 60, and one or more second chips 10b that are adjacent to chip 10a will be disabled and used in conjunction with chip 10a in order to provide external buffers and pads for the bond out chip 60. The chips 10a and 10b will be grouped together and cut in the fabrication process to form the bond out chip 60.

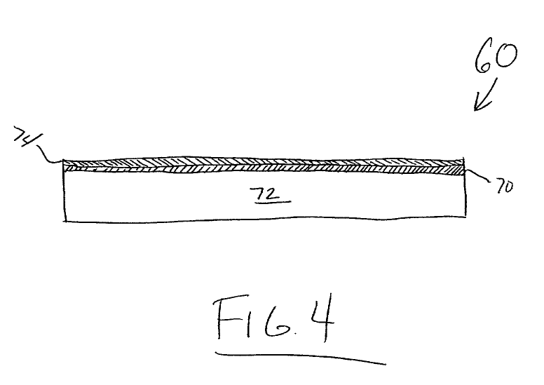

FIG. 3 illustrates a bond out chip 60 formed by chips 10a and 10b. While in the preferred embodiment of the invention, two single chips 10a and 10b are used to form a bond out chip 60, in other alternate embodiments any other number of disabled chips 10b may be used to provide input/output buffers and/or pads for the bond out chip 60. In the preferred embodiment, active chip 10a is substantially identical in structure and architecture to a standard production chip 10, with the exception that one or more connection layers of the chip 10a will be utilized to enable and connect driver circuits 26a and 28a. FIG. 4 illustrates a connection layer 70 formed on top of one or more other chip layers 72 that collectively form chip 60. The connection layer 70 is formed to activate core 12a, enable drivers 26a, 28a and to electrically connect drivers 26a, 28a to bus 30a, thereby communicatively connecting micro-control unit 14a to drivers 26a, 28a. The connection layer 70 is formed in a manner known in the art, effective create the electrical connections between the micro-control unit 14a and the drivers 26a, 28a (e.g., by use of buses 30a and 42a, 44a, respectively). The connection layer 70 will also be formed in a manner which disables the core 12b of the adjacent chip 10b. Particularly, the connection layer 70 will be formed so that nodes or locations 56b and 58b are disconnected from each other, thereby disconnecting the input/output buffers 18b from the core 12b (e.g., from the logic and input/output control unit of core 12b). While a single connection layer 70 is illustrated in FIG. 4, it should be appreciated that the present invention may use any suitable number of connection layers to achieve the foregoing connections and disconnections.

After the connection layer 70 is formed, an additional interconnection layer 74 is formed on top of the connection layer 70 of chip 60 in a conventional manner. The interconnection layer 74 is used to electrically connect chip 10a (e.g., drivers 26a and 28a of chip 10a ) to input/output buffers 18b and pads 20b. Particularly, the interconnection layer 74 traverses scribe line 64 and electrically connects nodes 52a, 54a of drivers 26a, 28a to input/output buffers 18b. Similarly, the interconnection layer 74 may be used to connect other points within the active chip 10a to input/output buffers 18b and pads 20b or to input/output buffers and pads on other adjacent chips (e.g., across other scribe lines). In alternate embodiments, layer 74 can be eliminated, and all necessary connections (e.g., connections between chip 10a and buffers 18b and/or pads 20b and across scribe line 64) may be formed by use of connection layer 70. In other alternate embodiments, buffers 18b may be bypassed and chip 10a can be communicatively connected directly to input/output pads 20b and/or to other input/output pads on other adjacent chips.

Once all connections have been made between chip 10a and the input/output buffers and/or pads of adjacent chip 10b and any other adjacent chips that are used to form the bond out chip 60, the bond out chip 60 may be removed from the wafer 50. Particularly, chips 10a, 10b (along with any other adjacent chips that may used to form the bond out chip 60) are removed together from the wafer 50, as a single chip or structure. The wafer 50 may be cut or divided along the associated scribe lines by use of any conventional semiconductor processing tool and/or method.

Since bond out chips 60 are formed by use of the same chips 10 that form standard production chips (i.e., the production chips that chips 60 are used to analyze or emulate), they may be produced in a cost-effective and efficient manner. Particularly, a substantially identical set of masks can be used for a chip 10 that is used to form part of a bond out chip 60, and for a standard production chip. The only exception is the connection layer 70 and interconnection layer 74, which are formed at the end of the fabrication process. This architecture substantially reduces the design and production time required to produce bond out chips 60. Furthermore, bond out chips 60 and standard production chips can be manufactured on the same wafer, thereby increasing production flexibility and reducing production costs. Additionally, because the bond out chips 60 and standard production chips share a majority of the same fabrication masks, tools and procedures, a change in the architecture of the production chips can be easily transferred to the bond out chips 60 without requiring the development of an entirely new design, mask set, and manufacturing procedures for the bond out chips 60.

It should be understood that the inventions described herein are provided by way of example only and that numerous changes, alterations, modifications, and substitutions may be made without departing from the spirit and scope of the inventions as delineated within the following claims.

What is claimed is:

1) A bond out chip comprising:
a first chip; and
a plurality of input/output pads which are disposed on at least second chip adjacent to said first chip and which are communicatively coupled to said first chip.

2) The bond out chip of claim 1 wherein said first chip and said at least one second chip are spaced apart and are separated by at least one scribe line.

3) The bond out chip of claim 1 wherein said first chip is substantially identical in architecture to a production chip with the exception of a connection layer.

4) The bond out chip of claim 3 wherein at least one second chip is substantially identical in architecture to said first chip, with the exception of a connection layer.

5) The bond out chip of claim 4 wherein said first chip and said at least one second chip are formed on a semiconductor wafer.

6) The bond out chip of claim 5 wherein said wafer has plurality of reticle zones, and said first chip and said at least one second chip each reside within the same reticle zone.

7) The bond out chip of claim 2 wherein said first chip includes an active core portion and said at least one second chip includes a disabled core portion.

8) The bond out chip of claim 7 wherein said disabled core portion is disabled by use of a at least one connection layer, said active core portion is activated by use of said at least one connection layer, and said plurality of input/output pads are communicatively coupled to said first chip by use of an interconnection layer which is disposed above said at least one connection layer and which traverses said at least one scribe line.

9) The bond out chip of claim 1 wherein said at least one second chip further comprises a plurality of input/output buffers which are communicatively coupled to said first chip.

10) The bond out chip of claim 1 wherein said first chip comprises a microcontroller.

11) A bond out chip formed on a semiconductor wafer comprising:
a first chip having an active core portion and which is substantially identical in architecture to a production chip with the exception of at least one connection layer; and
an adjacent chip which is substantially identical in architecture to said first chip with the exception of said at least one connection layer, which is spaced apart from said first chip and separated from said first chip by a scribe line, and which includes a disabled core portion and a plurality of input/output buffers and pads which are communicatively coupled to said first chip across said scribe line and which are adapted to allow said first chip to be coupled to an in-circuit emulator.

12) The bond out chip of claim 11 wherein said first chip further includes a plurality of drivers for communicating with said in-circuit emulator, and which are communicatively coupled to said plurality of input/output buffers and pads.

13) The bond out chip of claim 12 further comprising a connection layer for activating said plurality of drivers and communicatively coupling said input/output buffers and pads to said first chip.

14) The bond out chip of claim 13 wherein said first chip comprises a microcontroller.

15) A method of manufacturing a bond out chip, comprising the steps of:
forming a plurality of spaced apart chips on a semiconductor wafer each having a core portion and input/output pads;
activating the core portion of a first chip;
disabling the core portion of at least one second chip which is adjacent to said first chip;
connecting said first chip to the input/output pads of said at least one second chip; and
removing said first chip and second chip together from said wafer, thereby forming a bond out chip.

16) The method of claim 15 wherein the steps of activating the core portion of a first chip and disabling the core portion of at least one second chip are performed by forming a connection layer for said first chip and said at least one second chip.

17) The method of claim 16 wherein the step of connecting said first chip to the input/output pads of the at least one second chip is performed by forming an interconnection layer on top of said connection layer.

18) The method of claim 16 wherein the step of connecting said first chip to the input/output pads of the at least one second chip is performed by forming said connection layer.

19) The method of claim 15 wherein each of said chips is substantially similar in architecture.

20) The method of claim 19 wherein said chips are separated by scribe lines.
